(19) United States
(12) Patent Application Publication
(10) Pub. No.: US 2003/0130965 A1
(43) Pub. Date: Jul. 10, 2003

(54) Fuel dispenser that displays information based upon customer identity

(75) Inventors: Carl R. Jacobs, Bertram, TX (US); Jacqueline Collins, Austin, TX (US)

Correspondence Address: JENKENS & GILCHRIST, PC, 1445 ROSS AVENUE, SUITE 3200, DALLAS, TX, 75202, US

(73) Assignee: Dresser, Inc.

(21) Appl. No.: 10/043,699

(22) Filed: Jan. 9, 2002

(51) Int. Cl. G01R 11/56

(52) U.S. Cl. 705/412

(57) ABSTRACT

A fuel dispenser that displays information based upon the identity of the customer includes a user interface that permits the fuel dispenser to determine the identity of the customer. Once the fuel dispenser has determined the identity of the customer, the fuel dispenser displays information on a display that is customized as a function of the determined identity of the customer.

### BACKGROUND OF THE INVENTION

1. Technical Field of the Invention

This invention relates generally to systems for dispensing fuel, and in particular to a fuel dispenser that displays information to a customer using the dispenser.

2. Description of Related Art

Conventional fuel dispensers include displays that display predetermined information to customers using the fuel dispensers to dispense fuel. The displayed predetermined information may include advertisements for various products and services available from a convenience store at which the fuel dispenser is located. Conventional fuel dispensers do not permit the displayed information to be customized on a real-time basis based upon the characteristics of the customer.

The present invention is directed to overcoming one or more of the limitations of existing fuel dispensers.

### SUMMARY OF THE INVENTION

Provided is a new and unique fuel dispenser system, computing system and method for displaying information at a fuel dispenser. According to one embodiment, the fuel dispenser system includes fuel dispenser, a user interface, a display, a controller, a network interface, and one or more programming providers operably coupled to the network interface. The controller is operably coupled to the fuel dispensing equipment, the user interface, the network interface, and the display, and is adapted to determine the manner in which a user will pay to dispense fuel and display information on the display as a function of the manner in which the user will pay to dispense fuel. Though the information is displayed as a function of the manner in which the user will pay to dispense fuel, at least a portion of the information displayed is unrelated to the manner in which the user will pay. The controller is adapted to obtain at least a portion of the displayed information from one or more of the programming providers.

According to another embodiment, the controller is adapted to determine the identity of the user and display information on the display as a function of the identity of the user. The controller is adapted to obtain at least a portion of the displayed information from one or more of the programming providers.

According to another embodiment, a computing system is provided for use with a fuel dispenser. The computing system includes a medium for storing a plurality of software instructions. These software instructions are for determining a manner is which a user of the system will pay to dispense fuel, obtaining information from one or more remote sources of information, and displaying the information on the display as a function of the manner in which the user will pay to dispense the fuel. At least a portion of the information is unrelated to the manner in which the user will pay to dispense the fuel.

According to another embodiment, a method is provided for operating a fuel dispensing system including fuel dispensing equipment, a user interface, and a display. The identity of a user of the system is determined and, if desired, fuel may be dispensed. Information is shown on the display, the information being a function of the identity of the user. At least some of the displayed information is obtained from one or more remote sources of information.

The present embodiments of the invention provide a number of advantages. For example, the ability to provide customizable information to customers of the fuel dispensing system permits the operator of the system to maximize the commercial success of the system. Furthermore, because the displayed information is tailored for the customer, the customer receives information that is likely to be relevant and of benefit to the customer. As a result, customer loyalty is enhanced and the operator can also generate additional revenue streams by selling programming time for display to the customers.

### BRIEF DESCRIPTION OF THE DRAWINGS

FIG. 1b is a schematic illustration of an embodiment of the user interface of the fuel dispenser of the system of FIG. 1a.

FIG. 2 is a flow chart illustration of an embodiment of the operation of the system of FIG. 1 a.

FIG. 3 is a flow chart illustration of an alternative embodiment of the operation of the system of FIG. 1a.

FIG. 3a is a schematic illustration of an embodiment of a database of customer records for use in the system of FIG. 1a.

FIG. 3b is a schematic illustration of an embodiment of the customer records for use in the database of FIG. 3a.

FIG. 4 is a flow chart illustration of an alternative embodiment of the operation of the system of FIG. 1a.

FIG. 4a is a schematic illustration of an embodiment of a database including customer records for use in the system of FIG. 1a.

FIG. 4b is a schematic illustration of an embodiment of the customer records of the database of FIG. 4a.

### DETAILED DESCRIPTION OF THE EXEMPLARY EMBODIMENTS OF THE INVENTION

Referring to FIGS. 1a-1b, the reference numeral 100 refers, in general, to a fuel dispensing system according to an embodiment of the invention. The fuel dispensing system 100 includes a fuel dispenser 102 that includes a display 104, a user interface 106, and conventional fuel dispensing equipment 108 that are operably coupled to a controller 110. In an exemplary embodiment, the user interface 106 may include a keypad 106a to permit the user to enter alphanumeric information, a printer 106b for printing out receipts, coupons, and vouchers, a card reader 106c for receiving and processing information from a credit, debit, ATM, and/or smart card such as, for example, the user name, card number, card expiration date, and card issuer, a bar code reader 106d for reading bar coded information, a radio frequency (RF) or other type transceiver 106e for communicating with a payment transmitter carried by a customer or other device that can transmit information associated with a customer, and a biometrics interface 106f for making a retinal or fingerprint scan of the customer and thereby identifying the customer. In an exemplary embodiment, the controller 110 includes a programmable general purpose computer having an internal memory.

The controller 110 is also operably coupled to host computer 112 and programming providers, 114a and 114b, by a conventional network interface 116. In an exemplary embodiment, the conventional network interface 116 is the Internet. In an exemplary embodiment, the programming providers, 114a and 114b, are capable of providing programming such as advertisements, news, weather, sports, entertainment, driving directions, Internet access, and/or e-mail access to the controller 110 via the network 116 for display on the display 104 in a conventional manner.

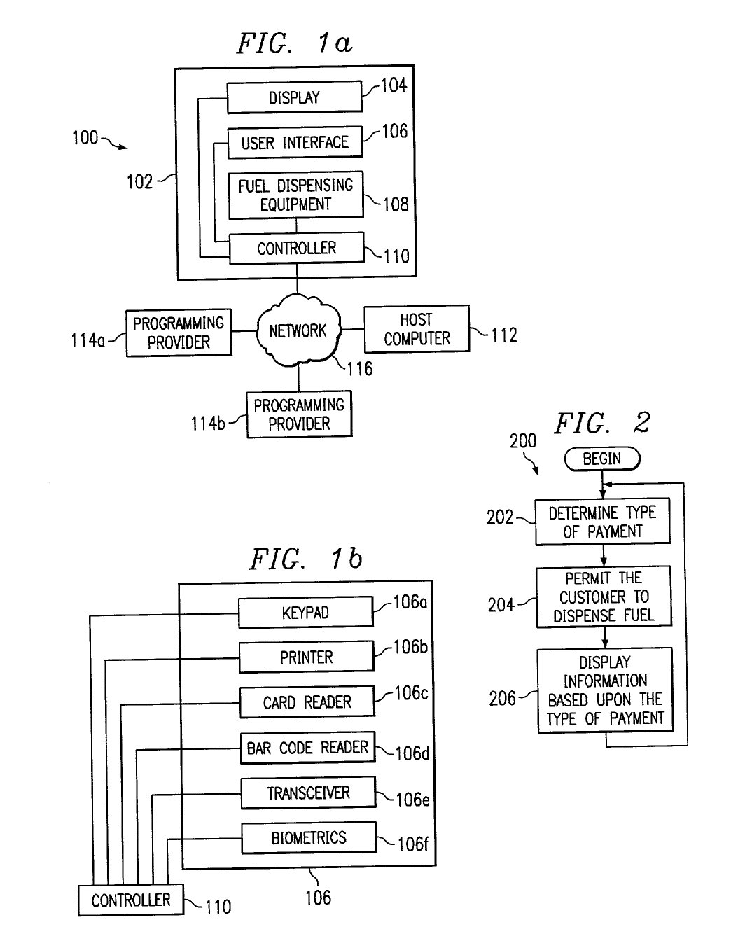

During operation of the system 100, as illustrated in FIG. 2, the controller 112 implements a program 200 for providing information to customers of the system in which the controller 110 determines the type of payment being used by a customer of the system in step 202. In an exemplary embodiment, the controller 110 determines the type of payment being used by the customer by monitoring the user interface 106. In an exemplary embodiment, the type of payment may include cash, credit card, debit card, ATM card, smart card, bar coded coupon, or RF or other type of payment transmitter.

The controller 110 then permits the customer to dispense fuel in step 204 by directing the fuel dispensing equipment to dispense the fuel.

The controller 110 then provides information for display on the display 104 as a function of the type of payment being used by the customer in step 206 while the customer dispenses fuel. In an exemplary embodiment, the displayed information is unrelated to the manner in which the user will pay to dispense fuel, and thus includes information other than, for example, the menu screens necessary to process payment by the chosen method. The displayed information can include advertising, news, weather, sports, entertainment, driving directions, Internet access, and/or e-mail access that is targeted to the customer as a function of the type of payment being used by the customer that is determined in step 202. In this manner, the displayed information may be customized for each customer of the system 100. In an exemplary embodiment, if the displayed information includes driving directions, Internet access, and/or e-mail access, the customer may then interact with the display 104 using the user interface 106 in a conventional manner. The manner in which advertising, news, weather, sports, entertainment, driving directions, Internet access, and/or e-mail access may be displayed on the display 104 by the controller 110 is considered well known in the art.

In an exemplary embodiment, at least a portion of the information provided for display on the display 104 in step 206 is transmitted from the host computer 112 and/or the programming providers, 114a and 114b, to the controller 110, and from the controller 110 to the display. In this manner, the operator of the system 100 may sell programming time on the display 104 to one or more of the programming providers, 14a and 14b, or other third parties, based upon the type of payment being used by the customer, on a real-time basis. Furthermore, the issuers of the credit, debit, ATM, and/or smart cards, and/or the payment transmitter may provide specialized programming for display on the display 104 in step 206 that is provided to the controller 110 by one or more of the programming providers 114. In this manner, promotional marketing campaigns may be conducted by the operator of the system 100 and/or the issuers of the credit, debit, ATM, and/or smart cards, and/or the payment transmitter that are targeted at specific customers.

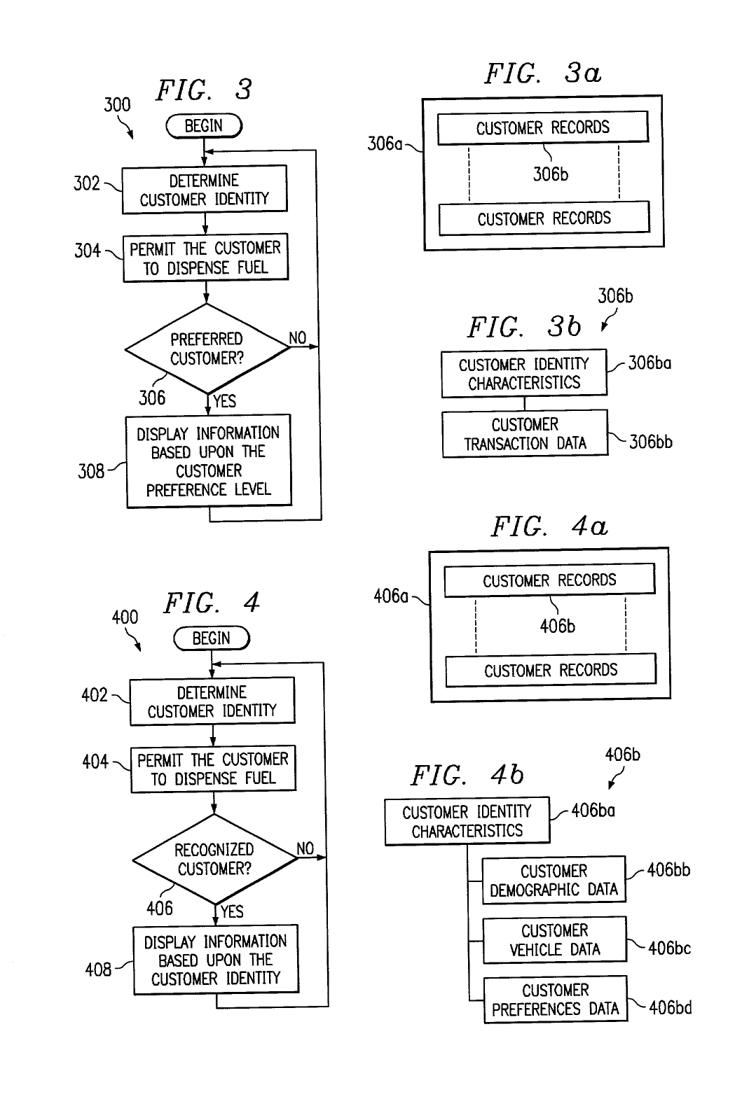

In an alternative embodiment, during operation of the system 100, as illustrated in FIGS. 3, 3a, and 3b, the controller 1 12 implements a program 300 for providing information to customers of the system in which the controller 110 determines the identity of the customer of the system in step 302. In an exemplary embodiment, the controller 110 determines the identity of the customer by monitoring the user interface 106. In an exemplary embodiment, the identity of the customer may include one or more of the following customer identity characteristics: (1) the name of the customer; (2) the name of the issuer of the credit, debit, ATM, or smart card or payment transmitter; (3) the account number of the customer associated with the credit, debit, ATM, or smart card, or payment transmitter; (4) a unique alpha numeric customer identifier; and/or (5) the biometrics for the customer.

The controller 110 then permits the customer to dispense fuel in step 304 by directing the fuel dispensing equipment to dispense the fuel.

The controller 110 then determines if the customer qualifies as a preferred customer in step 306 by accessing a customer database 306a that includes one or more customer records 306b that include customer identity characteristics 306ba and associated customer transaction data 306bb. If the customer is a first-time customer, then the controller 110 will generate a customer record 306b that includes the customer identity characteristics 306ba and associated customer transaction data 306bb for the customer. If the customer is a repeat customer, the controller 110 will retrieve and update the customer record 306b (including identity characteristics 306ba and transaction data 306bb) for the customer. In an exemplary embodiment, the customer database 306a may be maintained by the controller 110 and/or the host computer 112.

The controller 110 then provides information for display on the display 104 as a function of the customer's preferred status in step 308 while the customer dispenses fuel. In an exemplary embodiment, the determination of whether or not the customer is a preferred customer is made by comparing the number of times the customer has used the system 100 to dispense fuel within a predetermined time period with a predetermined target. If the number of times the customer has used the system 100 to dispense fuel within a predetermined time period is greater than or equal to the target, then preferred customer information is displayed on the display 104. If the number of times the customer has used the system 100 to dispense fuel within a predetermined time period is less than the target, then non-preferred customer information is displayed on the display 104.

In an alternative embodiment, in step 306, the controller 110 further determines the preference level of a preferred customer by comparing the number of times the customer has used the system 100 to dispense fuel within a predetermined time period against a plurality of predetermined preference metrics to thereby classify the customer as being in a lower preference class or a higher preference class. In an alternative embodiment, in step 308, the controller 110 then displays information on the display as a function of which preference class the customer was placed in step 306. In an exemplary embodiment, the lower preference class information includes news, weather, and sports, while, the higher preference class information includes news, weather, sports, Internet access, driving directions, and e-mail access.

In an alternative embodiment, the customer records 306b further include a value representative of the total dollar amount spent by the customer within a predetermined time period. In an alternative embodiment, in step 306, the controller 110 further determines the preference level of a preferred customer by comparing the number of times the customer has used the system 100 to dispense fuel within a predetermined time period and/or the total dollar amount spent by the customer within the predetermined time against a plurality of predetermined preference metrics, based upon number of customer visits and/or dollar amount spent, to thereby classify the customer as being in a lower preference class or a higher preference class. In an alternative embodiment, in step 308, the controller 110 then displays information on the display as a function of which preference class the customer was placed in step 306. In an exemplary embodiment, the lower preference class information includes news, weather, and sports, while, the higher preference class information includes news, weather, sports, Internet access, driving directions, and e-mail access.

In an exemplary embodiment, the preferred customer information includes advertising, news, weather, sports, entertainment, driving directions, Internet access, and/or e-mail access that is provided for display to the customer and may be provided as a function of the degree of preference for the customer. In an exemplary embodiment, if the displayed information includes driving directions, Internet access, and/or e-mail access, the customer may then interact with the display 104 using the user interface 106 in a conventional manner. In an exemplary embodiment, the non-preferred customer information includes advertising.

In an exemplary embodiment, at least a portion of the information provided for display on the display 104 in step 308 is transmitted from the host computer 112 and/or the programming providers, 114a and 114b, to the controller 110, and from the controller 110 to the display. In this manner, the operator of the system 100 may sell programming time on the display 104 to one or more of the programming providers, 14a and 14b, on a real-time basis.

In an alternative embodiment, during operation of the system 100, as illustrated in FIGS. 4, 4a, and 4b, the controller 112 implements a program 400 for providing information to customers of the system in which the controller 110 determines the identity of the customer of the system in step 402. In an exemplary embodiment, the controller 110 determines the identity of the customer by monitoring the user interface 106. In an exemplary embodiment, the identity of the customer may include one or more of the following customer identity characteristics: (1) the name of the customer; (2) the name of the issuer of the credit, debit, ATM, or smart card or payment transmitter; (3) the account number of the customer associated with the credit, debit, ATM, or smart card, or payment transmitter; (4) a unique alpha numeric customer identifier; and/or (5) the biometrics for the customer, and other identity characteristics of the customer. The identity of the customer can be determined in more general terms, for example, to group the customer together with other similar customers without determining the customer's specific identity. Thus the identity of the customer can also be determined using information such as whether the customer pays with cash, by credit, debit, ATM, smart card, or payment transmitter, the benefits level (ex. standard, gold, or platinum) of the customer's credit, debit, ATM, or smart card, the existence of, or information gathered from, an RF, infrared, or other transmitter device associated with the customer, for example, an automatic tollway payment device or a transmitting identifier associated with the vehicle, and other general identity characteristics of the customer.

The controller 110 then permits the customer to dispense fuel in step 404 by directing the fuel dispensing equipment to dispense the fuel.

The controller 110 then determines if the customer is a recognized customer in step 406 by accessing a customer database 406a that includes one or more customer records 406b that include customer identity characteristics 406ba and associated customer data including one or more of the following: customer demographic data 406bb; customer vehicle data 406bc; and customer preferences data 406bd. Alternately, the controller 110 can determine that the customer is a recognized customer in step 406 if, though the specific customer's identity is not recognized, the information collected about the customer identifies the customer with one or more predetermined profiles specifically set out in the customer records 406b for generalized identification of customers. Such generalized customer records 406b can include customer identity characteristics 406ba typical of the generalized customer.

In an exemplary embodiment, the customer demographic data 406bb includes one or more of the following: the customer's age, the customer's residence address, the customer's income, the customer's job title, and the customer's marital status. In an exemplary embodiment, the customer vehicle data 406bc includes one or more of the following: the customer's vehicle identification number, and the make, model, and year of the customer's vehicle. In an exemplary embodiment, the customer preferences data 406bd includes the type of programming that the customer would like to see displayed on the display 104. In an exemplary embodiment, the information contained within the customer records is provided by a customer by interfacing with the user interface 104 and/or by the customer providing the information to the system 100 offline by submitting a questionnaire through the mail or by accessing a website.

In an exemplary embodiment, in step 406, if the customer identity characteristics for the customer do not match any of the customer identity characteristics 406ba for the customer records 406b within the database 406a, then the customer is not a recognized customer. In an exemplary embodiment, in step 406, if the customer identity characteristics for the customer do match the customer identity characteristics 406ba for one of the customer records 406b within the database 406a, then the customer is a recognized customer.

If the customer is a recognized customer, the controller 110 then provides information for display on the display 104 as a function of the customer demographic data 406bb, the customer vehicle data 406bc, and/or the customer preferences data 406bd for the customer record 406a for the customer in step 408.

In an exemplary embodiment, if the information displayed in step 408 is displayed as a function of the customer demographic data 406bb, then the information is targeted at the customer as a function of the demographic information for the customer. In an exemplary embodiment, the operator of the system 100 may obtain at least some of the information for display in step 408 from the host computer 112 and/or the programming providers, 114a and 114b. In this manner, the operator of the system 100 may sell programming time on the display 104 to one or more of the programming providers, 14a and 14b, on a real-time basis. In an exemplary embodiment, the displayed information may include advertisements that may direct the customer to visit local businesses that cater to customer's having the demographic characteristics of the customer.

In an exemplary embodiment, if the information displayed in step 408 is displayed as a function of the customer vehicle data 406bc, then the information is targeted at the customer as a function of the customer vehicle information for the customer. In an exemplary embodiment, the operator of the system 100 may obtain at least some of the information for display in step 408 from the host computer 112 and/or the programming providers, 114a and 114b. In this manner, the operator of the system 100 may sell programming time on the display 104 to one or more of the programming providers, 14a and 14b, on a real-time basis. In an exemplary embodiment, the displayed information may include warranty and/or servicing and/or manufacturer recall information for the customer's vehicle, and/or sales and promotional information for local dealers of the make and model of the customer's vehicles.

In an exemplary embodiment, if the information displayed in step 408 is displayed as a function of the customer preferences data 406bd, then the information is targeted at the customer as a function of the customer preferences information for the customer. In an exemplary embodiment, the operator of the system 100 may obtain at least some of the information for display in step 408 from the host computer 112 and/or the programming providers, 114a and 114b. In this manner, the operator of the system 100 may sell programming time on the display 104 to one or more of the programming providers, 14a and 14b, on a real-time basis. In an exemplary embodiment, the displayed information may include news, weather, sports, financial information that are of particular interest to the customer, Internet access to particular websites of particular interest to the customer, driving directions for a trip specified by the customer, and /or e-mail access to the customer's e-mail account(s).

In an alternative embodiment, the customer may pay a subscription fee to the operator of the system 100 in order to provide a display of certain information. In this manner, the customer may, for a specified price, receive exactly what the customer specifies for display on the display 104.

The present embodiments of the invention provide a number of advantages. For example, the ability to provide customizable information to customers of the fuel dispensing system permits the operator of the system to maximize the commercial success of the system. Furthermore, because the displayed information is tailored for the customer, the customer receives information that is likely to be relevant and of benefit to the customer. Thus, the present embodiments permit the operator of the system to obtain a more preferred customer base and generate additional revenue streams from the sale of programming time on the system.

It is understood that variations may be made in the foregoing without departing from the scope of the invention. For example, the information provided to the customer on the display of the fuel dispenser could include programming such as news, weather and sports information, video clips, stock ticker information, as well as conventional cable and satellite television channels. Furthermore, the teachings of the various embodiments of the invention may be combined, in whole, or in part, to provide an adaptive fuel dispensing system that displays information to users on a real-time basis as a function of various metrics associated with the user's use of the fuel dispensing system.

Although illustrative embodiments of the invention have been shown and described, a wide range of modification, changes and substitution is contemplated in the foregoing disclosure. In some instances, some features of the present invention may be employed without a corresponding use of the other features. Accordingly, it is appropriate that the appended claims be construed broadly and in a manner consistent with the scope of the invention.

We claim:

1. A fuel dispensing system, comprising:
fuel dispensing equipment;
a user interface;
a display; and
a controller operably coupled to the fuel dispensing equipment, the user interface, and the display, the controller adapted to determine a manner in which a user will pay to dispense fuel and to display information on the display as a function of the manner in which the user will pay to dispense fuel;
wherein at least a portion of the display information is unrelated to the manner in which the user will pay to dispense fuel.

2. The fuel dispensing system of claim 1 further comprising a network interface operably coupled to the controller and connectable to one or more programming providers; and
wherein the controller is adapted to obtain at least some of the displayed information from one or more of the programming providers.

3. The fuel dispensing system of claim 2, wherein a plurality of programming providers are operably coupled to the network interface; and wherein the controller is adapted to obtain at least some of the displayed information from a plurality of the programming providers.

4. The system of claim 1, wherein the information is selected from the group consisting of advertising, news, weather, sports, financial news, entertainment, Internet access, driving directions, and e-mail access.

5. A computing system for use with a fuel dispensing system including fuel dispensing equipment, a user interface, and a display, comprising:
a medium for storing software instructions;
instructions stored on the medium for determining a manner in which a user of the system will pay to dispense fuel;
instructions stored on the medium for obtaining information from one or more remote sources of information; and
instructions stored on the medium for displaying the information on the display as a function of the manner in which the user will pay to dispense the fuel;
wherein at least a portion of the information is unrelated to the manner in which the user will pay to dispense the fuel.

6. The computing system of claim 5, further comprising:
instructions stored on the medium for obtaining the displayed information from a plurality of remote sources of information.

7. The computing system of claim 5 further comprising:
instructions stored on the medium for obtaining the displayed information from a plurality of remote sources of information.

8. The method of claim 7, further comprising:
obtaining at least some of the information from a plurality of remote sources of information; and
selecting a subset of the information for display, according to the identity of the user.

9. The method of claim 7, further comprising:
displaying information on the display as a function of whether or not the user is a preferred customer.

10. The method of claim 7, further comprising:
displaying information on the display as a function of the degree to which the user is a preferred customer.

11. The method of claim 7, further comprising:
displaying information on the display as a function of the vehicle information for the user.

12. The method of claim 11, wherein the information is selected from the group consisting of warranty information, servicing information, and manufacturer recall information for the customer's vehicle.

13. The method of claim 7, further comprising:
displaying information on the display as a function of the display preferences for the user.

14. The method of claim 7, further comprising:
maintaining a database comprising customer records that include customer identifiers and customer data.

15. The method of claim 14, wherein the customer data comprises transaction data representative of how often the user has dispensed fuel using the system within a predetermined time period.

16. The method of claim 14, wherein the customer data comprises transaction data representative of how much money the user has spent dispensing fuel using the system within a predetermined time period.

17. The method of claim 14, wherein the customer data comprises transaction data representative of how often the user has dispensed fuel using the system and how much money the user has spent dispensing fuel using the system within a predetermined time period.

18. The method of claim 14, wherein the customer data includes demographic data representative of the characteristics of the user.

19. The method of claim 14, wherein the customer data includes vehicle data representative of the identity of the user's vehicle.

20. The method of claim 14, wherein the customer data includes display preferences for the user.

21. The method of claim 14, further comprising:
retrieving one of the customer records associated with the user; and
processing the associated customer record to determine what to display on the display.

22. The method of claim 7, wherein the information is selected from the group consisting of advertising, news, weather, sports, financial news, entertainment, Internet access, driving directions, and e-mail access.

23. The method of claim 7, wherein the information is selected from the group consisting of warranty information, servicing information, and manufacturer recall information for the customer's vehicle.

24. The method of claim 7, wherein determining an identity of a user comprises determining that the user fits a profile for generalized identification of customers.
